(19) United States
(12) Patent Application Publication
(10) Pub. No.: US 2013/0214290 A1
(43) Pub. Date: Aug. 22, 2013

(54) METHOD FOR MANUFACTURING SILICON CARBIDE SEMICONDUCTOR DEVICE AND SILICON CARBIDE SEMICONDUCTOR DEVICE

(71) Applicant: Sumitomo Electric Industries, Ltd., (US)

(72) Inventors: Hideki Hayashi, Osaka-shi (JP); Takeyoshi Masuda, Osaka-shi (JP)

(73) Assignee: Sumitomo Electric Industries, Ltd., Osaka-shi (JP)

(21) Appl. No.: 13/738,636

(22) Filed: Jan. 10, 2013

Related U.S. Application Data
(60) Provisional application No. 61/599,625, filed on Feb. 16, 2012.

(30) Foreign Application Priority Data
Feb. 16, 2012 (JP) 2012-031389

(51) Int. Cl. H01L 29/66; H01L 29/16; H01L 29/78

(52) U.S. Cl. CPC H01L 29/66666; H01L 29/7827; H01L 29/1608
USPC 257/77; 438/270

(57) ABSTRACT

A silicon carbide layer having a first surface and a second surface includes a first region constituting the first surface and of a first conductivity type, a second region provided on the first region and of said second conductivity type, and a third region provided on the second region and of the first conductivity type. At the second surface is formed a gate electrode having a bottom and sidewall, passing through the third region and the second region up to the first region. An additional trench is formed, extending from the bottom of the gate trench in the thickness direction. A fourth region of the second conductivity type is formed to fill the additional trench.

### BACKGROUND OF THE INVENTION

1. Field of the Invention

The present invention relates to a method for manufacturing a silicon carbide semiconductor device and the silicon carbide semiconductor device. More particularly, the present invention relates to a method for manufacturing a silicon carbide semiconductor device having a gate trench, and the silicon carbide semiconductor device.

2. Description of the Background Art

It is known that there is a trade-off generally between the ON resistance and breakdown voltage in a semiconductor device for electric power. In recent years, there has been proposed a semiconductor device having a charge compensation structure such as a super junction structure for the purpose of improving the breakdown voltage while suppressing ON resistance. For example, Japanese Patent Laying-Open No. 2004-342660 discloses a power MOSFET (Metal Oxide Semiconductor Field Effect Transistor) having a charge compensation structure.

The aforementioned publication is silent about a charge compensation structure suitable for a silicon carbide semiconductor device having a gate trench.

### SUMMARY OF THE INVENTION

The present invention is directed to solve the aforementioned problem. An object of the present invention is to improve breakdown voltage while suppressing ON resistance in a silicon carbide semiconductor device having a gate trench.

A method for manufacturing a silicon carbide semiconductor device of the present invention includes the steps set forth below. A silicon carbide layer having a first surface and a second surface opposite to each other in a thickness direction is prepared. The silicon carbide layer includes a first region, a second region, and a third region. The first region constitutes the first surface, and is of a first conductivity type. The second region is provided on the first region so as to be apart from the first surface by the first region, and is of a second conductivity type differing from the first conductivity type. The third region is provided on the second region, isolated from the first region by the second region, and is of the first conductivity type. At the second surface, a gate trench having a bottom and a sidewall, passing through the third region and the second region up to the first region is formed. The sidewall has a region constituted of each of the first region, the second region, and the third region. An additional trench is formed, extending from the bottom of the gate trench in the thickness direction. A fourth region of a second conductivity type is formed to fill the additional trench. A gate insulation film is formed, covering the second region of the silicon carbide layer on the sidewall. A gate electrode is formed on the second region of the silicon carbide layer with the gate insulation film therebetween. A first electrode is formed on the first region of the silicon carbide layer. A second electrode is formed on the third region of the silicon carbide layer.

According to the silicon carbide semiconductor device obtained by the present manufacturing method, at least a portion of the electric field in the thickness direction caused by fixed charge of one of the positive and negative polarity generated by depletion of the first region is compensated for by the fixed charge of the other polarity generated by depletion of the fourth region. In other words, a charge compensation structure is provided. Accordingly, the maximum value of the electric field intensity in the thickness direction is suppressed. Therefore, the breakdown voltage of the silicon carbide semiconductor device can be improved.

Preferably, the fourth region is formed to have a thickness greater than 5 μm in the thickness direction. Accordingly, a charge compensation structure is provided over a greater range in the thickness direction. Thus, the breakdown voltage of the silicon carbide semiconductor device can be further improved.

Preferably, the step of forming an additional trench includes the steps of forming a mask on the silicon carbide layer, covering the sidewall and exposing the bottom of the gate trench, and etching the bottom using the mask. Accordingly, the sidewall of the gate trench can be protected by the mask during formation of the additional trench.

Preferably, the mask is removed after the fourth region is formed and before the gate insulation film is formed. Accordingly, an unnecessary region generated during film growth for forming the fourth region can be removed together with the mask.

Preferably, the step of forming a fourth region includes the step of heating the silicon carbide layer up to a heating temperature. The mask has a melting point higher than the heating temperature. Accordingly, the silicon carbide layer can be heated together with the mask.

Preferably, the step of forming a mask includes the step of forming a tantalum carbide film. Accordingly, the melting point of the mask can be set higher.

Preferably, the step of removing the mask includes the step of oxidizing the tantalum carbide film. Accordingly, the mask can be removed readily.

Preferably in the manufacturing method set forth above, the step of forming an additional trench is carried out through etching having a physical etching action. Accordingly, the etching directed to forming an additional trench can be carried out more perpendicularly. Therefore, the side face of the fourth region formed in the additional trench can be set along the thickness direction. Thus, the charge compensation by the fourth region can be effected sufficiently.

Preferably in the manufacturing method set forth above, the step of forming a gate trench is carried out by thermal etching. Accordingly, the plane orientation of the sidewall of the gate trench can be set to a specific one crystallographically.

A silicon carbide semiconductor device of the present invention includes a silicon carbide layer, a gate insulation film, a gate electrode, a first electrode, and a second electrode. The silicon carbide layer includes a first surface and a second surface opposite to each other in a thickness direction. The silicon carbide layer includes a first region, a second region, a third region, and a fourth region. The first region constitutes the first surface, and is of a first conductivity type. The second region is provided on the first region apart from the first surface by the first region, and is of a second conductivity type differing from the first conductivity type. The third region is provided on the second region, isolated from the first region by the second region, and is of the first conductivity type. At the second surface, a gate trench having a bottom and a sidewall is provided, passing through the third and second regions up to the first region. The sidewall has a region constituted of each of the first region, the second region, and the third region. The silicon carbide layer includes a fourth region provided at the bottom, isolated from the first surface by the first region, and of the second conductivity type. The fourth region has a thickness greater than 5 μm in the thickness direction. The gate insulation film covers the second region of the silicon carbide layer on the sidewall. The gate electrode is formed on the second region of the silicon carbide layer via the gate insulation film. The first electrode is provided on the first region of the silicon carbide layer. The second electrode is provided on the third region of the silicon carbide layer.

According to the present device, at least a portion of the electric field in the thickness direction caused by fixed charge of one of the positive and negative polarity generated by depletion of the first region is compensated for by the fixed charge of the other polarity generated by depletion of the fourth region. In other words, a charge compensation structure is provided. Accordingly, the maximum value of the electric field intensity in the thickness direction is suppressed. Therefore, the breakdown voltage of the silicon carbide semiconductor device can be improved.

Preferably in the present device set forth above, the sidewall of the gate trench is oblique to the second surface of the silicon carbide layer by an angle greater than 0° and smaller than 90°. Accordingly, a channel plane having a plane orientation oblique to the second surface can be provided.

More preferably, the angle of the side face of the fourth region relative to the thickness direction is small as compared to the angle of the sidewall of the gate trench relative to the thickness direction. Accordingly, the charge compensation by virtue of the fourth region can be effected more sufficiently.

The silicon carbide layer may have a crystal structure of hexagonal system. In this case, the sidewall of the gate trench of the silicon carbide layer preferably includes a region constituted of at least one of the {0-33-8} plane and {0-11-4} plane. Accordingly, the carrier mobility on the sidewall can be increased. Therefore, the ON resistance of the silicon carbide semiconductor device can be suppressed.

The silicon carbide layer may have a crystal structure of cubic system. In this case, the sidewall of the gate trench of the silicon carbide layer preferably includes a region constituted of the {100} plane. Accordingly, the carrier mobility on the sidewall can be increased. Therefore, the ON resistance of the silicon carbide semiconductor device can be suppressed.

The first electrode may be formed directly on or indirectly on the first region.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial sectional view schematically representing a configuration of a silicon carbide semiconductor device according to an embodiment of the present invention.

FIG. 2 is a partial sectional view taken along line II-II in each of FIGS. 3-5, schematically representing a configuration of a silicon carbide layer in the silicon carbide semiconductor device of FIG. 1.

FIGS. 3 and 4 are a partial perspective view and a partial plan view, respectively, schematically representing a configuration of the silicon carbide layer in FIG. 2.

FIG. 5 is a partial plan view showing in further detail a configuration of the silicon carbide layer in FIG. 4.

FIG. 6 is a partial sectional view schematically representing a first step in a method for manufacturing a silicon carbide semiconductor device according to an embodiment of the present invention.

FIG. 7 is a partial plan view schematically representing a second step in the method for manufacturing a silicon carbide semiconductor device according to an embodiment of the present invention.

FIG. 8 is a schematic partial sectional view taken along line VIII-VIII in FIG. 7.

FIG. 9 is a partial sectional view schematically representing a third step in the method for manufacturing a silicon carbide semiconductor device according to an embodiment of the present invention.

FIG. 10 is a partial plan view schematically representing a fourth step in the method for manufacturing a silicon carbide semiconductor device according to an embodiment of the present invention.

FIG. 11 is a schematic partial sectional view taken along line XI-XI in FIG. 10.

FIGS. 12-20 are partial sectional views schematically representing fifth to thirteenth steps, respectively, in the method for manufacturing a silicon carbide semiconductor device according to an embodiment of the present invention.

### DESCRIPTION OF THE PREFERRED EMBODIMENTS

Embodiments of the present invention will be described hereinafter based on the drawings. In the drawings set forth below, the same or corresponding elements have the same reference characters allotted, and description thereof will not be repeated. As to the crystallographic notation in the present specification, a specific plane is represented by ( ) whereas a group of equivalent planes is represented by { }. For a negative index, a bar (−) is typically allotted above a numerical value in the crystallographic aspect. However, in the present specification, a negative sign will be attached before the numerical value.

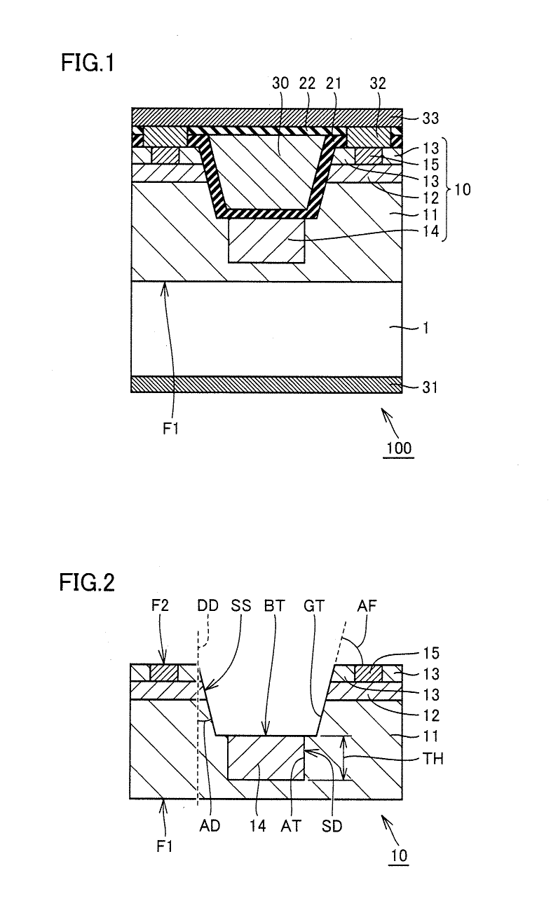

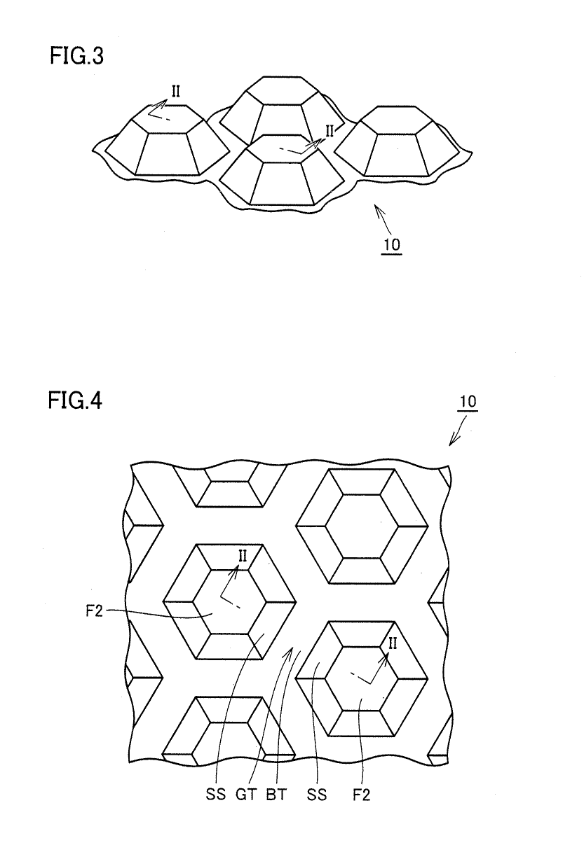

First, a structure of an MOSFET 100 (silicon carbide semiconductor device) according to the present embodiment will be described with reference to FIGS. 1-5.

As shown in FIG. 1, MOSFET 100 includes a single crystal substrate 1, a SiC layer 10 (silicon carbide layer), a drain electrode 31 (first electrode), a source electrode 32 (second electrode), a gate oxide film 21 (gate insulation film), an interlayer insulation film 22, a gate electrode 30, and a source interconnection layer 33.

Single crystal substrate 1 is made of silicon carbide of the n-type (first conductivity type). For example, single crystal substrate 1 is formed of silicon carbide having a single crystal structure of either hexagonal system or cubic system. Preferably, a main surface (the top face in the drawing) having an off angle within 5 degrees from the reference plane is provided at single crystal substrate 1. The reference plane is the {000-1} plane, more preferably the (000-1) plane, for the hexagonal system. For the cubic system, the reference plane is the {111} plane. Preferably, the off angle is greater than or equal to 0.5 degrees.

Further referring to FIGS. 2-5, SiC layer 10 has a lower face F1 (first surface) and an upper face F2 (second surface) opposite to each other in the thickness direction DD (FIG. 2). Lower face F1 and upper face F2 are substantially parallel to each other. SiC layer 10 includes an n⁻ drift region 11 (first region), a p region 12 (second region), an n region 13 (third region), a charge compensation region 14 (fourth region), and a p⁺ contact region 15. N⁻ drift region 11 constitutes lower face F1, and is of the n-type (first conductivity type. P region 12 is provided on n⁻ drift region 11, and is of the p-type (the second conductivity type differing from the first conductivity type). N region 13 is provided on p region 12, isolated from n⁻ drift region 11 by p region 12, and is of the n-type (first conductivity type).

At upper face F2 is provided a gate trench GT having a bottom BT and a sidewall SS, passing through n region 13 and p region 12 up to n⁻ drift region 11. Sidewall SS includes a region constituted of each of n⁻ drift region 11, p region 12, and n region 13. The impurity concentration of n⁻ drift region 11 is preferably greater than or equal to 5×10¹⁵ cm⁻³ and less than or equal to 5×10¹⁷ cm⁻³, more preferably greater than or equal to 5×10¹⁵ cm⁻³ and less than or equal to 5×10¹⁶ cm⁻³.

Charge compensation region 14 is of the p-type (the second conductivity type). Charge compensation region 14 is provided at a bottom BT of gate trench GT. Charge compensation region 14 is isolated from drain electrode 31 by n⁻ drift region 11. Charge compensation region 14 has a thickness TH (FIG. 2) greater than 5 μm in thickness direction DD. The impurity concentration of charge compensation region 14 is preferably greater than or equal to 1×10¹⁶ cm⁻³ and less than or equal to 1×10¹⁸ cm⁻³, more preferably greater than or equal to 1×10¹⁶ cm⁻³ and less than or equal to 1×10¹⁷ cm⁻³. The impurity concentration of charge compensation region 14 is preferably higher than the impurity concentration of n⁻ drift region 11. This is because the width occupied by charge compensation region 14 (the horizontal dimension in FIG. 2) is smaller than the width occupied by n⁻ drift region 11 at the height position where charge compensation region 14 is provided (the position in the vertical direction in FIG. 2).

P⁺ contact region 15 is directly provided on a portion of p region 12, and constitutes a portion of upper face F2 of SiC layer 10.

Gate oxide film 21 covers p region 12 of SiC layer 10 on sidewall SS. Gate electrode 30 is provided on gate oxide film 21 of SiC layer 10 with gate oxide film 21 therebetween.

Drain electrode 31 is an ohmic electrode provided on n⁻ drift region of n⁻ drift region 11 of SiC layer 10 with single crystal substrate 1 therebetween. Source electrode 32 is an ohmic electrode directly provided on n region 13 and p⁺ contact region 15 of SiC layer 10.

Preferably, sidewall SS of gate trench GT is oblique relative to upper face F2 of SiC layer 10 by just an angle AF (FIG. 2) greater than 0° and smaller than 90°. More preferably, the angle of a side face SD (FIG. 2) of charge compensation region 14 relative to thickness direction DD is smaller as compared to an angle AD (FIG. 2) of sidewall SS of gate trench GT relative to thickness direction DD.

SiC layer 10 may have a crystal structure of hexagonal system. In this case, sidewall SS of gate trench GT of SiC layer 10 preferably includes a region constituted of at least one of a {0-33-8} plane and {0-11-4} plane. SiC layer 10 may have a crystal structure of cubic system. In this case, sidewall SS of gate trench GT of SiC layer 10 preferably includes a region constituted of the {100} plane.

A method for manufacturing MOSFET 100 will be described hereinafter.

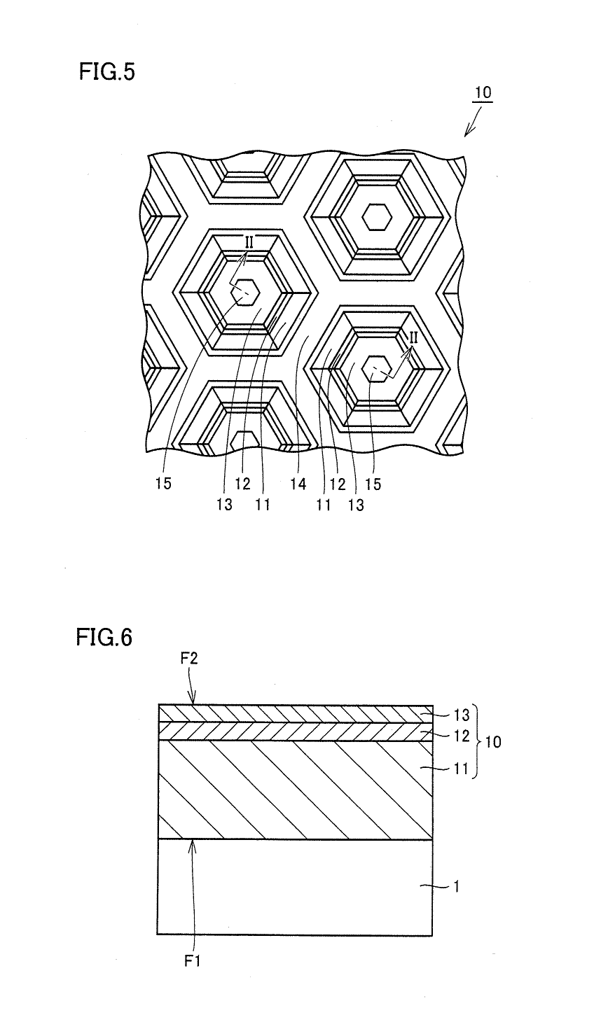

As shown in FIG. 6, SiC layer 10 including the portion constituting n⁻ drift region is formed by epitaxial-growth of silicon carbide on single crystal substrate 1. The epitaxial-growth of silicon carbide can be carried out by chemical vapor deposition (CVD) using mixture gas of silane (SiH₄) and propane (C₃H₈) as the raw material gas and hydrogen gas (H₂) as the carrier gas. Silicon carbide can be doped n-type by using nitrogen (N) or phosphorus (P), for example, for the impurities.

P region 12 and n region 13 are formed from a portion of SiC layer 10. Specifically, ions are implanted onto the upper surface layer of SiC layer 10 to form p region 12 and n region 13. The portion not subject to ion implantation remains as n⁻ drift region 11. By adjusting the acceleration energy of the implanted ions, the region where p region 12 is formed can be adjusted. In impurity ion implantation for applying p-type, aluminium (Al), for example, is employed for the impurities. In impurity ion implantation for applying n-type, phosphorus (P), for example, is employed for the impurities. At least one of p region 12 and n region 13 may be formed by epitaxial growth instead of ion implantation.

Thus, SiC layer 10 having a stacked structure of n⁻ drift region 11, p region 12 and n region 13 in the cited order is formed on single crystal substrate 1. SiC layer 10 includes a lower face F1 and an upper face F2 opposite to each other in the thickness direction (in the drawing, the vertical direction). Lower face F1 faces single crystal substrate 1.

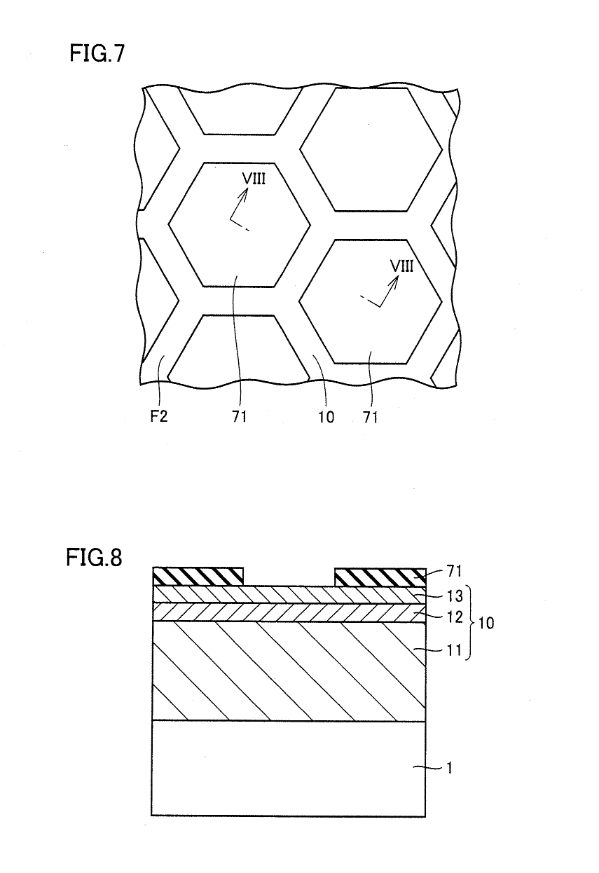

As shown in FIGS. 7 and 8, a mask layer 71 is formed on upper face F2 of SiC layer 10. Mask layer 71 has an opening corresponding to the position where gate trench GT (FIG. 1) is to be formed. Mask layer 71 is formed of silicon oxide (SiO₂), for example.

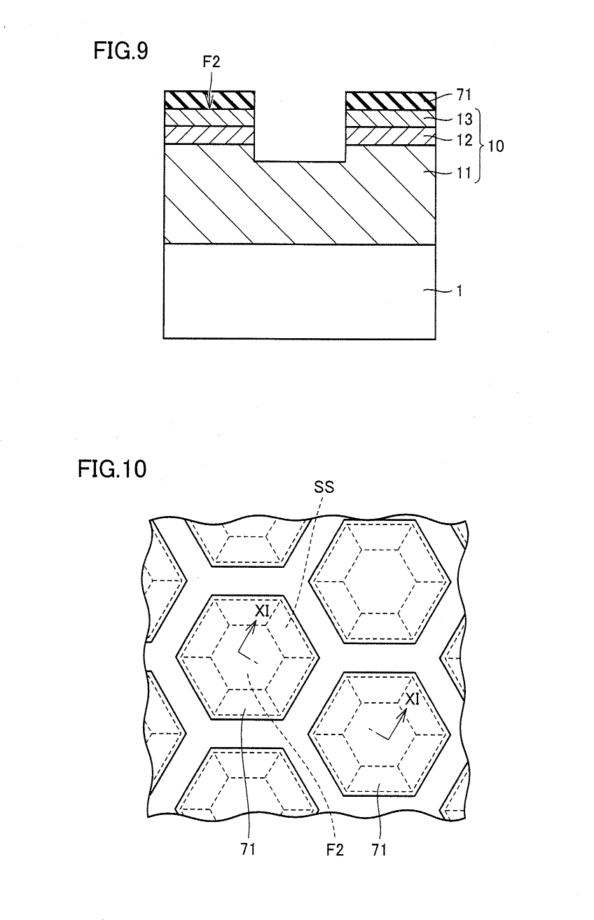

As shown in FIG. 9, by etching using mask layer 71, a recess is formed on upper face F2 of SiC layer 10 at the opening of mask layer 71. Preferably this etching is carried out through etching having a physical etching action. For such etching, reactive ion etching (RIE) or ion beam etching (IBE), for example, can be cited. Particularly, inductive coupling plasma (ICP) RIE can be used for RIE. Specifically, ICP-RIE using SF₆ or mixture gas of SF₆ and O₂ as the reaction gas can be employed.

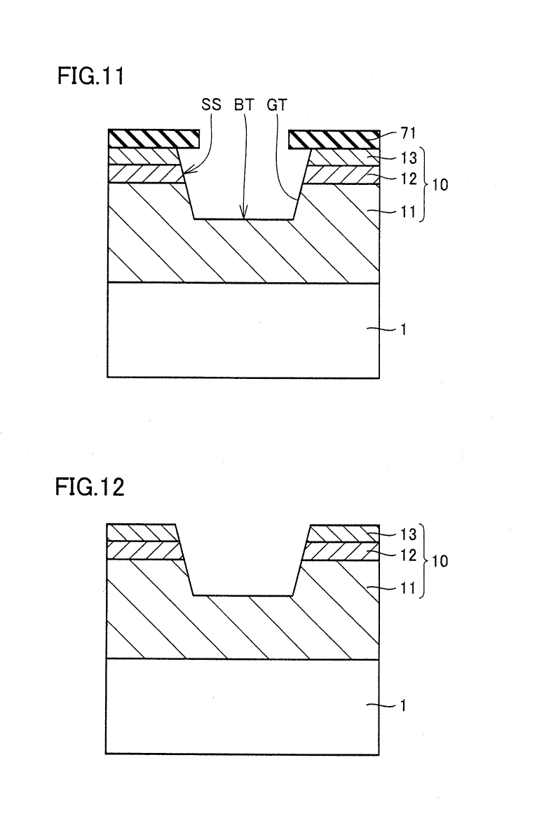

As shown in FIGS. 10 and 11, by thermal etching of SiC layer 10 using a mask layer 71, there is formed a gate trench GT having a bottom BT and a sidewall SS at upper face F2, passing through n region 13 and p region 12 up to n⁻ drift region 11. The details of thermal etching will be described afterwards. Then, mask layer 71 is removed (FIG. 12).

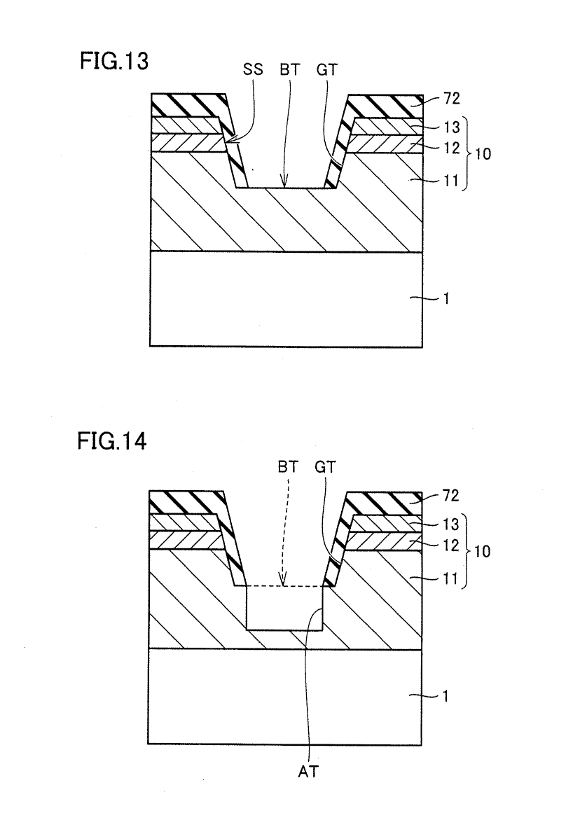

As shown in FIG. 13, a mask 72 is formed on SiC layer 10, covering sidewall SS and exposing bottom BT of gate trench GT. Mask 72 preferably has a melting point higher than the temperature required for epitaxial growth of silicon carbide. For example, a tantalum carbide film is formed as mask 72.

As shown in FIG. 14, bottom BT is etched using mask 72. Accordingly, there is formed an additional trench AT, extending from bottom BT of gate trench GT in the thickness direction (in the drawing, the vertical direction). During etching, sidewall SS of gate trench GT is protected by mask 72. Preferably, this etching is effected through etching having a physical etching action.

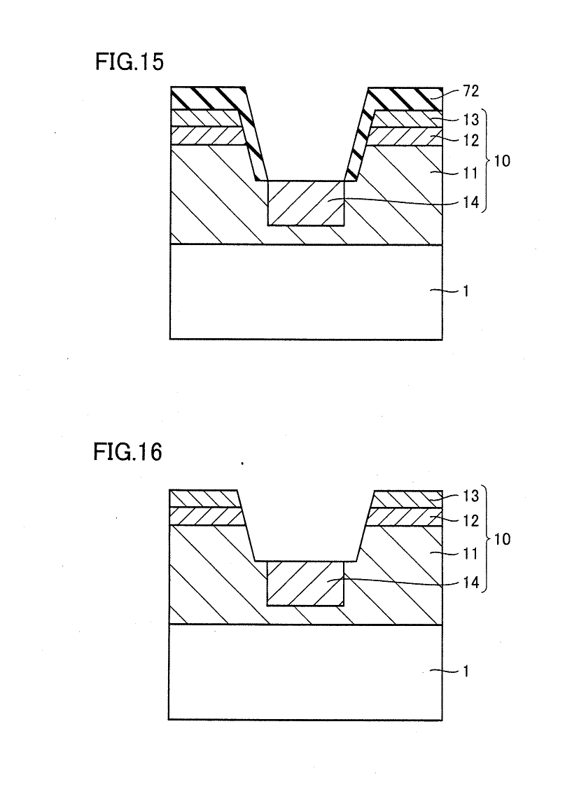

As shown in FIG. 15, charge compensation region 14 is formed to fill additional trench AT. Specifically, while heating SiC layer 10 up to a predetermined heating temperature, epitaxial growth of silicon carbide is carried out in additional trench AT. The heating temperature is lower than the melting point of mask 72. Epitaxial growth may be carried out by CVD, for example. Then, mask 72 is removed (FIG. 16). In the case where mask 72 includes a tantalum carbide film, oxidation of the tantalum carbide film may be carried out for removing mask 72.

Charge compensation region 14 does not necessarily have to be formed so as to fill additional trench AT precisely. Charge compensation region 14 may be formed to not reach the boundary between additional trench AT and gate trench GT, or may be formed beyond this border. Preferably, charge compensation region 14 is formed to have a thickness TH greater than 5 μm in thickness direction DD.

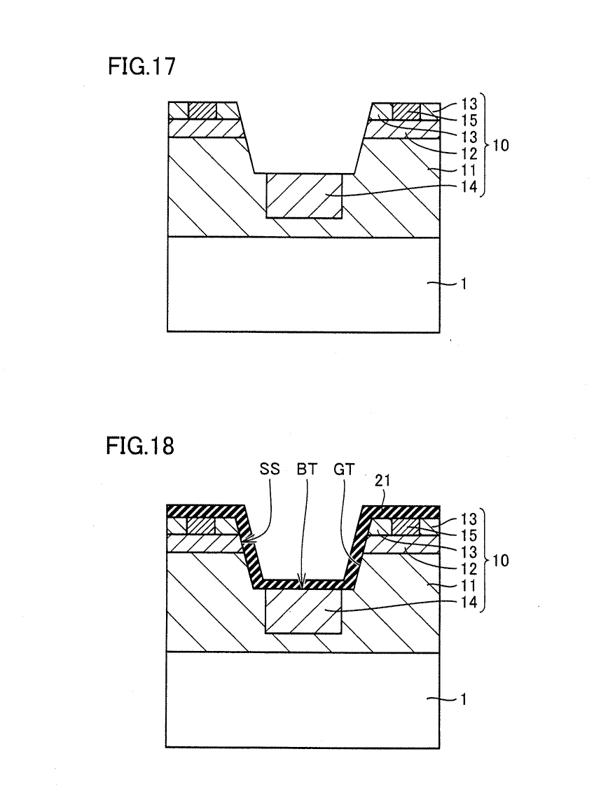

As shown in FIG. 17, p⁺ contact region 15 is formed by impurity ion implantation. Then, activation annealing is carried out to activate the impurities implanted by ion implantation. For example, heating is carried out at the temperature of 1700° C.. for 30 minutes.

As shown in FIG. 18, the exposed face of SiC layer 10 is subjected to thermal oxidation to form gate oxide film 21. Since the inner face of gate trench GT is also subjected to thermal oxidation during this step, gate oxide film 21 covers p region 12 of SiC layer 10 on sidewall SS. Furthermore, gate oxide film 21 covers charge compensation region 14 of SiC layer 10 on bottom BT.

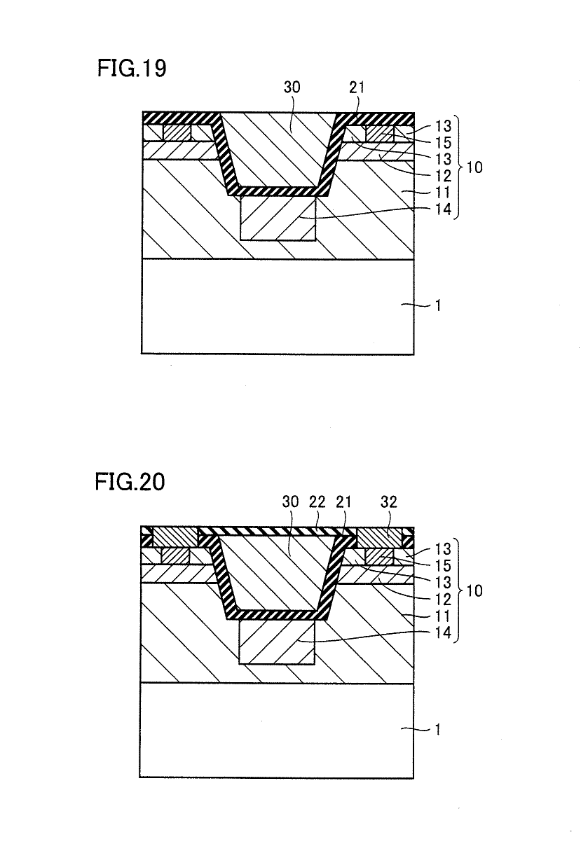

As shown in FIG. 19, gate electrode 30 is formed in gate trench GT. Gate electrode 30 is formed to have a portion located on p region 12 of SiC layer 10 with gate oxide film 21 therebetween.

Referring to FIG. 20, interlayer insulation film 22 is formed on the exposed gate oxide film 21 and gate electrode 30 (FIG. 19). By gate oxide film 21 and interlayer insulation film 22 being subjected to patterning, an opening is formed, exposing p⁺ contact region 15 and a portion of n region 13. Then, source electrode 32 is formed in this opening. Thus, the configuration shown in FIG. 20 is obtained.

Referring to FIG. 1 again, source interconnection layer 33 is formed on interlayer insulation film 22 and source electrode 32. Further, drain electrode 31 is formed on n⁻ drift region 11, i.e. on lower face F1 of SiC layer 10, with single crystal substrate 1 therebetween. Thus, MOSFET 100 is obtained.

Thermal etching employed in the above-described manufacturing method will be set forth below. Thermal etching is based on chemical reaction occurring by supplying process gas including reactive gas to an etching target heated up to a predetermined thermal treatment temperature.

For the reactive gas in the process gas, gas containing chlorine atoms, preferably chlorine based gas, more preferably chlorine gas, is employed. Thermal etching is preferably carried out under an atmosphere in which the partial pressure of the chlorine based gas is less than or equal to 50%. The process gas preferably includes oxygen atoms, for example, oxygen gas. In the case where chlorine gas and oxygen gas are both employed, the ratio of the flow rate of oxygen gas to the flow rate of chlorine gas is preferably greater than or equal to 0.1 and less than or equal to 2.0, more preferably the lower limit of this ratio is 0.25, in supplying process gas. Further, the process gas may include carrier gas. For the carrier gas, nitrogen gas, argon gas, helium gas, or the like, for example, may be employed. Thermal etching is carried out preferably under reduced pressure, and more preferably, the pressure is less than or equal to 1/10 the pressure of the atmosphere.

The thermal treatment temperature is preferably greater than or equal to 700° C.., more preferably greater than or equal to 800° C.., and further preferably greater than or equal to 900° C.. Accordingly, the etching rate can be increased. Furthermore, the thermal treatment temperature is preferably less than or equal to 1200° C.., more preferably less than or equal to 1100° C.., and further preferably less than or equal to 1000° C.. Accordingly, the device used for thermal etching can be a simpler one. For example, a device using a quartz member may be employed.

Mask layer 71 for thermal etching (FIG. 11) is preferably made of silicon oxide. Accordingly, the consumption of the mask during etching can be suppressed.

By the thermal etching set forth above, a crystal plane having high chemical stability and crystallographically specific can be provided in self-formation as sidewall SS (FIG. 2) of gate trench GT. The crystal plane formed may include at least one of a {0-33-8} plane and {0-11-4} plane when the crystal structure of SiC layer 10 corresponds to the hexagonal system. When the crystal structure thereof corresponds to the cubic system, the crystal plane may include the {100} plane.

The method of using MOSFET 100 (FIG. 1) and the functional effect of the present embodiment will be described hereinafter.

MOSFET 100 is used as a switching element for switching the current path between drain electrode 31 and source interconnection layer 33. A positive voltage relative to source interconnection layer 33 is applied to drain electrode 31. When a positive voltage greater than or equal to the threshold voltage is applied to gate electrode 30, an inversion layer is present at p region 12 on sidewall SS of gate trench GT, i.e. at the channel region. Therefore, n⁻ drift region 11 is electrically connected to n region 13, which is an ON state of MOSFET 100.

When application of a voltage greater than or equal to the threshold voltage to gate electrode 30 is stopped, the aforementioned inversion layer is eliminated. Therefore, carrier supply from source interconnection layer 33 towards n⁻ drift region 11 is stopped. As a result, depletion proceeds from the pn junction plane by n⁻ drift region 11 and p region 12 towards drain electrode 31. Thus, n⁻ drift region 11 and charge compensation region 14 are depleted.

The positive fixed charge of depleted n⁻ drift region 11 becomes a factor in increasing the electric field intensity in the thickness direction on the pn junction plane. Depleted charge compensation region 14 has negative fixed charge, which cancels at least a portion of the aforementioned electric field intensity. In other words, charge compensation region 14 functions as a charge compensation structure. Accordingly, the maximum value of the electric field intensity in the thickness direction is suppressed. Thus, the breakdown voltage of MOSFET 100 can be improved. More preferably, the aforementioned canceling is performed thoroughly. In this case, the total charge in the charge compensation structure becomes zero, so that the inclination of the electric field in the thickness direction in the charge compensation structure becomes zero. Therefore, a higher breakdown voltage can be achieved.

Charge compensation region 14 has a thickness TH preferably greater than 5 μm in thickness direction DD (FIG. 2). Accordingly, the charge compensation structure is provided over a larger range in thickness direction DD. Thus, the breakdown voltage of MOSFET 100 can be further improved. When thickness TH is greater than 5 μm, the avalanche breakdown can be set to approximately 500 V or greater.

Mask 72 used for etching additional trench AT (FIGS. 13 and 14) is removed after charge compensation region 14 is formed. Therefore, an unnecessary portion generated during film growth for forming charge compensation region 14 can be removed together with mask 72. Specifically, amorphous silicon carbide generated on mask 72 during formation of charge compensation region 14 made of single crystalline silicon carbide can be removed.

During formation of additional trench AT, etching having a physical etching function is preferably employed. Accordingly, the etching directed to forming additional trench AT can be carried out more perpendicularly. Therefore, side face SD (FIG. 2) of charge compensation region 14 formed in additional trench AT can be set along thickness direction DD. Thus, charge compensation by virtue of charge compensation region 14 can be effected more sufficiently. In the present embodiment, thermal etching is employed in forming gate trench

GT. Accordingly, the plane orientation of sidewall SS of gate trench GT can be provided in self-formation as a crystallographically specific one. Preferably, sidewall SS of gate trench GT is oblique by just an angle AF (FIG. 2) greater than 0° and smaller than 90°, relative to upper face F2 of SiC layer 10. Accordingly, a channel plane having a plane orientation oblique to upper face F2 can be provided on sidewall SS of gate trench GT. More preferably, the angle of side face SD (FIG. 2) of charge compensation region 14 relative to thickness direction DD is smaller than angle AD of sidewall SS of gate trench GT relative to thickness direction DD. Accordingly, the charge compensation by virtue of charge compensation region 14 can be effected more sufficiently.

SiC layer 10 may have a crystal structure of hexagonal system. In this case, sidewall SS of gate trench GT of SiC layer 10 preferably includes a region constituted of at least one of the {0-33-8} plane and {0-11-4} plane. Accordingly, the carrier mobility on sidewall SS can be increased. Therefore, the ON resistance of MOSFET 100 can be suppressed.

SiC layer 10 may have a crystal structure of cubic system. In this case, sidewall SS of gate trench GT of SiC layer 10 preferably includes a region constituted of the {100} plane. Accordingly, the carrier mobility on sidewall SS can be increased. Therefore, the ON resistance of MOSFET 100 can be suppressed.

In the method for manufacturing MOSFET 100, a step of thinning single crystal substrate 1 may be carried out before forming drain electrode 31 (FIG. 1). In the extreme case, single crystal substrate 1 may be removed. In this context, MOSFET 100 (FIG. 1) is absent of single crystal substrate 1, and drain electrode 31 will be directly provided on n⁻ drift region 11, i.e. on bottom face F1.

Further, gate trench GT may be formed by dry etching, other than thermal etching. For example, gate trench GT may be formed by RIE or IBE, for example. Moreover, gate trench GT may be formed by etching other than dry etching, for example, by wet etching. The sidewalls of the gate trench facing each other do not necessarily have to be in a non-parallel position relationship, as shown in FIG. 1. The sidewalls may take a parallel relationship with respect to each other.

In the embodiment set forth above, the region of upper face F2 surrounded by sidewall SS of gate trench GT has a hexagonal shape, as shown in FIG. 4. The shape of this region is not limited to a hexagon, and may be a rectangle (including a square), for example. For this shape, a hexagon in which each corner has an angle of approximately 60° is preferable when the crystal structure of SiC layer 10 is hexagonal. In the case where the crystal structure is cubic, a rectangle is preferable.

The first conductivity type is not limited to the n-type, and may be the p-type. The MOSFET is of the n channel type when the first conductivity type is the n-type, and is of the p channel type when the first conductivity type is the p-type.

Moreover, the silicon carbide semiconductor device is not limited to an MOSFET, and may be an MISFET (Metal Insulator Semiconductor Field Effect Transistor) other than an MOSFET.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide semiconductor device comprising the steps of:
preparing a silicon carbide layer having a first surface and a second surface opposite to each other in a thickness direction, said silicon carbide layer including a first region constituting said first surface and of a first conductivity type, a second region provided on said first region apart from said first surface by said first region, and of a second conductivity type differing from said first conductivity type, and a third region provided on said second region, and isolated from said first region by said second region, and of said first conductivity type, and
forming a gate trench having a bottom and a sidewall, at said second surface, passing through said third region and said second region up to said first region, said sidewall including a region constituted of each of said first region, said second region, and said third region, and
forming an additional trench extending from said bottom of said gate trench in said thickness direction,
forming a fourth region of said second conductivity type so as to fill said additional trench,
forming a gate insulation film on said sidewall, covering said second region of said silicon carbide layer,
forming a gate electrode on said second region of said silicon carbide layer with said gate insulation film therebetween,
forming a first electrode on said first region of said silicon carbide layer, and
forming a second electrode on said third region of said silicon carbide layer.

2. The method for manufacturing a silicon carbide semiconductor device according to claim 1, wherein, in said step of forming a fourth region, said fourth region is formed to have a thickness greater than 5 μm in said thickness direction.

3. The method for manufacturing a silicon carbide semiconductor device according to claim 1, wherein said step of forming an additional trench includes the steps of
forming a mask on said silicon carbide layer, covering said sidewall and exposing said bottom of said gate trench, and
etching said bottom using said mask.

4. The method for manufacturing a silicon carbide semiconductor device according to claim 3, further comprising the step of removing said mask, after said step of forming a fourth region and before said step of forming a gate insulation film.

5. The method for manufacturing a silicon carbide semiconductor device according to claim 4, wherein
said step of forming a fourth region includes the step of heating said silicon carbide layer up to a heating temperature, and
said mask has a melting point higher than said heating temperature.

6. The method for manufacturing a silicon carbide semiconductor device according to claim 5, wherein said step of forming a mask includes the step of forming a tantalum carbide film.

7. The method for manufacturing a silicon carbide semiconductor device according to claim 6, wherein said step of removing said mask includes the step of oxidizing said tantalum carbide film.

8. The method for manufacturing a silicon carbide semiconductor device according to claim 1, wherein said step of forming an additional trench is carried out through etching having a physical etching action.

9. The method for manufacturing a silicon carbide semiconductor device according to claim 1, wherein said step of forming a gate trench is carried out using thermal etching.

10. A silicon carbide semiconductor device comprising:
a silicon carbide layer having a first surface and a second surface opposite to each other in a thickness direction, said silicon carbide layer including a first region constituting said first surface and of a first conductivity type, a second region provided on said first region apart from said first surface by said first region, and of a second conductivity type differing from said first conductivity type, and a third region provided on said second region, and isolated from said first region by said second region, and of said first conductivity type, and a gate trench having a bottom and a sidewall being provided at said second surface, passing through said third region and said second region up to said first region, said sidewall including a region constituted of each of said first region, said second region, and said third region, said silicon carbide layer including a fourth region provided at said bottom, isolated from said first surface by said first region, and of said second conductivity type, said fourth region having a thickness greater than 5 μm in said thickness direction, and
a gate insulation film covering said second region of said silicon carbide layer on said sidewall,
a gate electrode provided on said second region of said silicon carbide layer with said gate insulation film therebetween,
a first electrode provided on said first region of said silicon carbide layer, and
a second electrode provided on said third region of said silicon carbide layer.

11. The silicon carbide semiconductor device according to claim 10, wherein said sidewall of said gate trench is oblique to said second surface of said silicon carbide layer by an angle larger than 0° and smaller than 90°.

12. The silicon carbide semiconductor device according to claim 11, wherein an angle of a side face of said fourth region relative to said thickness direction is smaller than an angle of said sidewall of said gate trench relative to said thickness direction.

13. The silicon carbide semiconductor device according to claim 10, wherein
said silicon carbide layer has a crystal structure of hexagonal system, and
said sidewall of said gate trench of said silicon carbide layer includes a region constituted of at least one of a {0-33-8} plane and {0-11-4} plane.

14. The silicon carbide semiconductor device according to claim 10, wherein
said silicon carbide layer has a crystal structure of cubic system, and
said sidewall of said gate trench of said silicon carbide layer includes a region constituted of a {100} plane.
